(19) United States
(12) Patent Application Publication
(10) Pub. No.: US 2026/0244285 A1
(43) Pub. Date: Aug. 20, 2026

(54) DRIVE CIRCUIT, ACTIVE PEN, AND TOUCH PANEL

(71) Applicant: SHENZHEN GOODIX TECHNOLOGY CO., LTD., Shenzhen (CN)

(72) Inventors: Zhichao PENG, Shenzhen (CN); Le ZHANG, Shenzhen (CN); Bo LI, Shenzhen (CN)

(73) Assignee: SHENZHEN GOODIX TECHNOLOGY CO., LTD., Shenzhen (CN)

(21) Appl. No.: 19/184,209

(22) Filed: Apr. 21, 2025

Related U.S. Application Data
(63) Continuation of application No. PCT/CN2023/120752, filed on Sep. 22, 2023.

(30) Foreign Application Priority Data
Nov. 7, 2022 (CN) 202211386986.1
Feb. 8, 2023 (WO) PCT/CN2023/074918

(51) Int. Cl. G06F 3/038; G06F 3/0354; G06F 3/041; G06F 3/044; H03K 17/687

(52) U.S. Cl. CPC G06F 3/0383; G06F 3/03545; G06F 3/0416; G06F 3/0442; H03K 17/6872

(57) ABSTRACT

A drive circuit, an active pen, and a touch panel are provided. The circuit comprises a first voltage generation circuit, at least one energy storage element, and a switch circuit. The first voltage generation circuit and the at least one energy storage element are connected to a load through the switch circuit, the first voltage generation circuit is configured to output a first power supply voltage; and the switch circuit is configured to control the first voltage generation circuit to charge the load in a first phase until a voltage of the load reaches the first power supply voltage, control the load to discharge to the at least one energy storage element sequentially in a second phase, control the load to discharge to ground in a third phase, and control the at least one energy storage element to charge the load sequentially in a fourth phase.

### CROSS REFERENCE

The present disclosure is a continuation application of PCT/CN2023/120752 filed on Sep. 22, 2023 and entitled “DRIVE CIRCUIT, ACTIVE PEN, AND TOUCH PANEL”, which claims priority to PCT application No. PCT/CN2023/074918 filed on Feb. 8, 2023 and entitled “DRIVE CIRCUIT, TOUCH CONTROL DRIVING APPARATUS, AND ELECTRONIC DEVICE”, and the Chinese Application No. 202211386986.1 filed on Nov. 7, 2022 and entitled “TOUCH CONTROL DRIVE CIRCUIT AND TOUCH CONTROL DRIVE METHOD”, which are incorporated herein by references in its entirety.

### TECHNICAL FIELD

Embodiments of the present disclosure relate to the field of circuits, and more specifically relate to a drive circuit, an active pen, and a touch panel.

### BACKGROUND

With the popularization of capacitive screens and active pens, the application of capacitive active pens has become increasingly extensive. In general, a pen tip electrode of an active pen can output a high-voltage square wave drive signal to a touch panel, and a touch chip of the touch panel can determine coordinate information of the pen tip based on the drive signal, wherein the larger the amplitude of the voltage outputted from the pen tip electrode is, the higher the detection sensitivity of the touch system is, and the more accurate the detection is. However, this also increases power consumption of the active pen, thereby greatly restricting the application of this method in a less power-consuming scenario such as a portable active pen. Therefore, how to increase an amplitude of a signal outputted from the pen tip electrode of the active pen without increasing power consumption has become a to-be-solved problem.

### SUMMARY

An embodiment of the present disclosure provides a drive circuit, an active pen, and a touch panel, which can increase an amplitude of a signal outputted from the drive circuit without increasing power consumption.

In a first aspect, a drive circuit configured to provide a drive voltage to a capacitive load is provided. The drive circuit comprises a first voltage generation circuit, at least one energy storage element, and a switch circuit, wherein the first voltage generation circuit and the at least one energy storage element are connected to the load through the switch circuit, the first voltage generation circuit is configured to output a first power supply voltage; and the switch circuit is configured to control the first voltage generation circuit to charge the load in a first phase until a voltage of the load reaches the first power supply voltage, control the load to discharge to the at least one energy storage element sequentially in a second phase, control the load to discharge to ground in a third phase, and control the at least one energy storage element to charge the load sequentially in a fourth phase, so that the voltage of the load rises and falls stepwise between different phases.

In an embodiment of the present disclosure, the first voltage generation circuit and the at least one energy storage element are arranged in the drive circuit, to charge or discharge the load sequentially, so that the voltage of the load varies stepwise after each charge phase or discharge phase. Compared with the case where the drive circuit directly outputs a square wave signal, the stepwise rise or fall of the voltage can effectively reduce power consumption of the power source, and increase an amplitude of a signal outputted from the drive circuit without increasing the power consumption.

In some possible implementations, the drive circuit further comprises a second voltage generation circuit, the second voltage generation circuit is connected in parallel with a first energy storage element among the at least one energy storage element, the second voltage generation circuit is configured to output a second power supply voltage, and the second power supply voltage is smaller than the first power supply voltage, wherein, in the second phase, the load discharges to the first energy storage element until the voltage of the load reaches the second power supply voltage, and in the fourth phase, the first energy storage element charges the load until the voltage of the load reaches the second power supply voltage.

In this embodiment, the second voltage generation circuit in parallel with the first energy storage element is arranged in the drive circuit. The second voltage generation circuit is configured to output the second power supply voltage, and can maintain the voltage of the load at the second power supply voltage during charge transfer between the first energy storage element and the load, thereby effectively regulating a voltage value corresponding to each step.

For example, the second supply voltage may be set to half of the first supply voltage.

In some possible implementations, the at least one energy storage element further comprises a second energy storage element, and the switch circuit is specifically configured to control the load to discharge to the first energy storage element and the second energy storage element sequentially in the second phase, and control the second energy storage element and the first energy storage element to sequentially charge the load in the fourth phase; wherein, in the second phase, the load discharges to the second energy storage element until the voltage of the load reaches half of the second power supply voltage, and in the fourth phase, the second energy storage element charges the load until the voltage of the load reaches half of the second power supply voltage.

In this embodiment, the drive circuit comprises the first voltage generation circuit, the first energy storage element, the second energy storage element, and a ground voltage that are connected to the load respectively, thereby forming four corresponding branch circuits. The four branch circuits are switched on alternately, thereby obtaining a drive voltage with four steps in each of voltage rising stages and voltage falling stages, wherein voltages corresponding to the four steps are the first power supply voltage, the second power supply voltage, half of the second power supply voltage, and the ground voltage respectively.

In some possible implementations, the switch circuit comprises a first switch unit, a second switch unit, a third switch unit, and a fourth switch unit, wherein the first switch unit is connected between the first voltage generation circuit and the load, the second switch unit is connected between the first energy storage element and the load, the third switch unit is connected between the second energy storage element and the load, and the fourth switch unit is connected between the load and ground; the first switch unit is configured to be switched on in the first phase, so that the first voltage generation circuit charges the load until the voltage of the load reaches the first power supply voltage, the second switch unit is configured to be switched on in a first sub-phase of the second phase, to discharge the load to the first energy storage element until the voltage of the load reaches the second power supply voltage, the third switch unit is configured to be switched on in a second sub-phase of the second phase, to discharge the load to the second energy storage element until the voltage of the load reaches half of the second power supply voltage, the fourth switch unit is configured to be switched on in the third phase, to discharge the load to ground until the voltage of the load reaches a ground voltage, the third switch unit is further configured to be switched on in a third sub-phase of the fourth phase, so that the second energy storage element charges the load until the voltage of the load reaches half of the second power supply voltage, and the second switch unit is further configured to be switched on in a fourth sub-phase of the fourth phase, so that the first energy storage element charges the load until the voltage of the load reaches the second power supply voltage.

The conduction sequence of each switch circuit among the switch circuits is reasonably controlled, thereby respectively implementing the processes of charging the load by the first voltage generation circuit, discharging the load to the at least one energy storage element, discharging the load to ground, and charging the load by the at least one energy storage element respectively in different phases, and obtaining a stepwise rising and falling drive voltage.

In some possible implementations, a switch unit connected between the first voltage generation circuit and the load in the switch circuit comprises a PMOS device, and a switch unit connected between each energy storage element and the load in the switch circuit comprises two groups of switches in parallel, wherein the first group of switches comprise a PMOS device and a diode in series, the second group of switches comprise an NMOS device and a diode in series, the diode in the first group of switches and the diode in the second group of switches have opposite conduction directions, and a switch unit connected between the load and the ground in the switch circuit comprises an NMOS device.

For example, when applied to a high-voltage driving scenario, the PMOS device is a P-type LDMOS device, and the NMOS device is an N-type LDMOS device.

In some possible implementations, a dead time for switch switching is set between the first phase and the second phase, the dead time is not set between at least one sub-phase in the second phase for discharging the load to the at least one energy storage element and between the second phase and the third phase, the dead time is set between the third phase and the fourth phase, and the dead time is not set between at least one sub-phase in the fourth phase for charging the load by the at least one energy storage element.

In this embodiment, the first group of switches and the second group of switches in parallel are arranged between each energy storage element and the load, the first group of switches comprise a PMOS device and a diode in series, the second group of switches comprise an NMOS device and a diode in series, and the diode in the first group of switches and the diode in the second group of switches have opposite conduction directions, so that the first group of switches and the second group of switches are configured to control corresponding branch circuits as a pure charging branch circuit and a pure discharging branch circuit respectively. Even if different PMOS devices are switched on simultaneously, a sink current will not be formed in relevant branch circuits, so that it is not necessary to set the corresponding dead time, thereby simplifying the complexity of the switch control logic.

In some possible implementations, the first voltage generation circuit is a charge pump circuit, and the second voltage generation circuit is a boost circuit. The charge pump circuit cooperates with the boost circuit to control a voltage value corresponding to each step, which is conducive to improving the efficiency of the drive circuit.

In some possible implementations, the energy storage element is an energy storage capacitor, and the first energy storage element in parallel with the second voltage generation circuit multiplexes a voltage stabilizing capacitor of the second voltage generation circuit. Using a capacitor as an energy storage element can be easily implemented, and the energy storage element in parallel with the second voltage generation circuit can multiplex the voltage stabilizing capacitor of the second voltage generation circuit, thereby reducing the costs.

In some possible implementations, a branch circuit where at least a part of energy storage elements among the at least one energy storage element are located is configured to have enabling and disabling functions. For example, when the branch circuit is enabled, the branch circuit is used for charging and discharging the load, while when the branch circuit is disabled, the branch circuit is prohibited from charging and discharging the load. Some branch circuits are configured to be enabled or disabled, thereby flexibly controlling the number of the steps of the drive voltage.

In some possible implementations, the load is a pen tip electrode of a capacitive active pen, or the load is a touch electrode in a touch panel.

In a second aspect, an active pen is provided, comprising the drive circuit according to the first aspect or any one possible implementation in the first aspect and a pen tip electrode connected to the drive circuit, wherein the drive circuit is configured to provide a drive voltage to the pen tip electrode.

In a third aspect, a touch panel is provided, comprising the drive circuit according to the first aspect or any one possible implementation in the first aspect and a touch electrode connected to the drive circuit, wherein the drive circuit is configured to provide a drive voltage to the touch electrode.

### BRIEF DESCRIPTION OF DRAWINGS

FIG. 1 is a schematic diagram of a drive circuit of a conventional active pen.

FIG. 2 is a schematic diagram of a drive voltage outputted from the drive circuit shown in FIG. 1.

FIG. 3 is a schematic diagram of a drive circuit in an embodiment of the present disclosure.

FIG. 4 is a schematic diagram of a drive voltage source outputted from the drive circuit shown in FIG. 3.

FIG. 5 is a schematic diagram of another drive circuit in an embodiment of the present disclosure.

FIG. 6 is a schematic block diagram of still another drive circuit in an embodiment of the present disclosure.

FIG. 7 is a schematic structural diagram of two voltage generation circuits comprised in the drive circuit shown in FIG. 6.

FIG. 8 is a schematic diagram of a possible specific implementation of the drive circuit shown in FIG. 7.

FIG. 9 is a schematic diagram of another possible specific implementation of the drive circuit shown in FIG. 7.

FIG. 10 is a schematic diagram of a drive voltage outputted from the drive circuit shown in FIG. 8.

FIG. 11 is a schematic diagram of a drive voltage outputted from the drive circuit shown in FIG. 9.

FIG. 12 is a schematic diagram of a possible specific implementation of the drive circuit shown in FIG. 9.

FIG. 13 is a schematic diagram of a drive voltage and a switching sequence outputted from the drive circuit shown in FIG. 12.

### DETAILED DESCRIPTION

Technical solutions of the present disclosure will be described below with reference to the drawings.

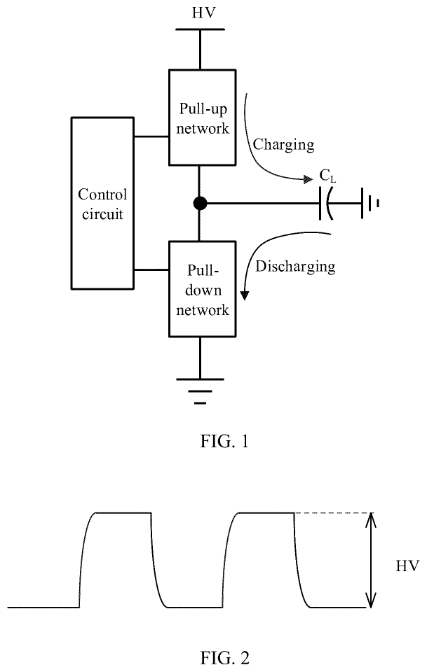

In touch systems of some active pens, a pen tip electrode of an active pen can output a drive signal, or referred to as a driving g signal, to a touch panel. The drive signal may be, for example, a square wave signal. A touch chip of the touch panel detects the drive signal, thereby determining coordinate information of the pen tip of the active pen. The larger the amplitude of the voltage outputted from the pen tip electrode is, the higher the detection sensitivity of the touch system is, and the higher the detection precision is. For example, FIG. 1 is a schematic diagram of a drive circuit of a conventional active pen. The drive circuit comprises a pull-up network and a pull-down network. A control circuit drives the pull-up network and the pull-down network through a control signal at a frequency f to push-pull and output a square wave signal of high-voltage pulse width modulation (PWM) as shown in FIG. 2, and alternately charges and discharges a load capacitor C_{L}. As shown in FIG. 2, the amplitude of the square wave signal ranges from 0 to HV, wherein the HV is a power supply voltage. Power of effective work made by the power source in a process of outputting the drive signal from the drive circuit can be calculated as P=C_{L}×HV²×f.

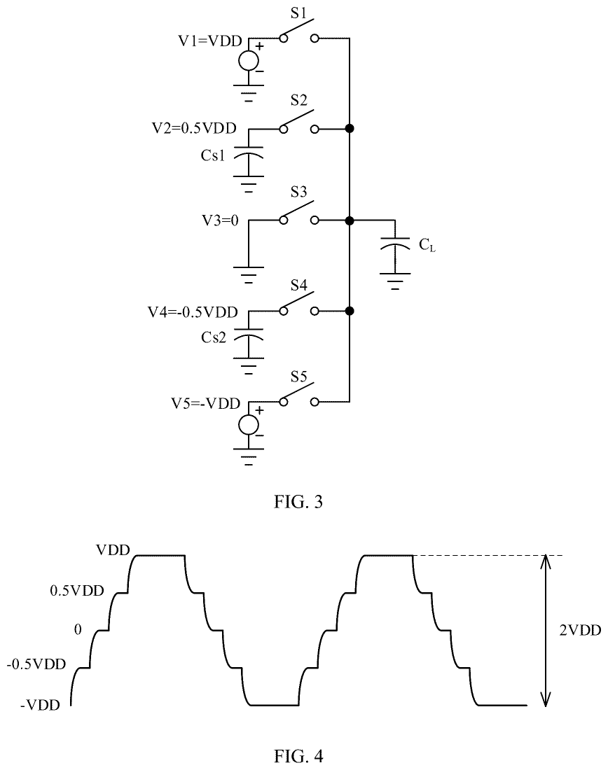

In order to obtain a drive signal with a larger amplitude, in an embodiment of the present disclosure, the peak value of the drive signal can be extended to 2VDD by introducing a positive power supply voltage VDD and a negative power supply voltage −VDD. Based on analysis of the drive circuit shown in FIG. 1, a relationship between power P of the effective work made by a power source in the process of outputting the drive signal from the drive circuit and the power supply voltage HV satisfies P∝HV², that is, when the amplitude of the drive signal is doubled, the power of the power source will increase by four times. Therefore, to reduce power consumption of the power source, as shown in FIGS. 3 and 4, a stepped drive signal, also known as a step wave signal, is introduced into the drive circuit, to reduce elevated amplitude of the waveform of the drive signal outputted from the drive circuit in each stage, thereby reducing the drive current and reducing the power consumption of the power source. As shown in FIGS. 3 and 4, at the same frequency f, in a same cycle of the drive signal, the positive power source V1 transfers charges to the load and generates power consumption only in a stage when the output voltage of the load capacitor C_{L} rises from 0.5 VDD to VDD. Therefore, the average current consumed by the power source in the process of outputting the drive signal from the drive circuit is 0.5×VDD×C_{L}×f, and the corresponding average power consumption is P1=0.5×C_{L}×VDD²×f. Similarly, the average power consumption generated by the negative power source V5 is P2=0.5×C_{L}×VDD²×f, and the total power consumption of the two power sources is P=P1+P2=C_{L}×VDD²×f. Based on comparison between the drive circuit shown in FIG. 3 and the conventional drive circuit shown in FIG. 1, when VDD=HV, for equal power consumption, the amplitude of the step wave drive signal shown in FIG. 4 is twice as much as the amplitude of the square wave drive signal shown in FIG. 2. That is, for equal drive signal amplitude, the power consumption required by a step wave drive signal is half of the power consumption required by the square wave drive signal. However, due to the time when the step wave drive signal has a step the amplitude of its harmonic signal at the frequency f is somewhat lost, and is close to, but fails to reach, 100% of the amplitude of the harmonic signal at the frequency f of the square wave drive signal with an amplitude of 2VDD.

The drive circuit for outputting the step wave drive signal can form a corresponding branch circuit by a plurality of power sources, capacitors, and switches, and is finally “wired-AND” to the load capacitor C_{L} at the output terminal, for example, each branch circuit is directly connected to the load capacitor C_{L}. The load capacitor C_{L} is, for example, an equivalent capacitor of the pen tip electrode of the active pen. As shown in FIG. 3, when the drive circuit is working normally, the control circuit successively controls switches S1 to S5 to be switched on alternately in the following sequence: S5→S4→S3→S2→S1→S2→S3→S4→S5→ . . . , thereby alternately switching on each branch circuit. In each stage, only one switch is switched on, to charge or discharge the load capacitor C_{L}, thereby outputting the voltage step as shown in FIG. 4. Cₛ₁ and Cₛ₂ shown in the drive circuit shown in FIG. 3 are energy storage capacitors. Compared with the load capacitor C_{L}, they have the following relationship: Cₛ₁=Cₛ₂>>C_{L}, wherein the symbol “>>” means “much larger than”. For example, in an application of the active pen, the C_{L} may be in a magnitude of pF, such as in a range of 10 pF-20 pF, while Cₛ₁ and Cₛ₂ are larger than C_{L} by at least one magnitude. The intermediate plateau voltages V2=0.5×VDD, V4=−0.5×VDD are formed because in a stage when the switches S2 and S4 are switched on, charges are transferred and redistributed between Cₛ₁ and C_{L}, and between Cₛ₂ and C_{L}, which is achieved by self-equilibrium based on the law of charge conservation. Therefore, no additional voltage source is required for biasing to generate the two intermediate voltage steps V2 and V4.

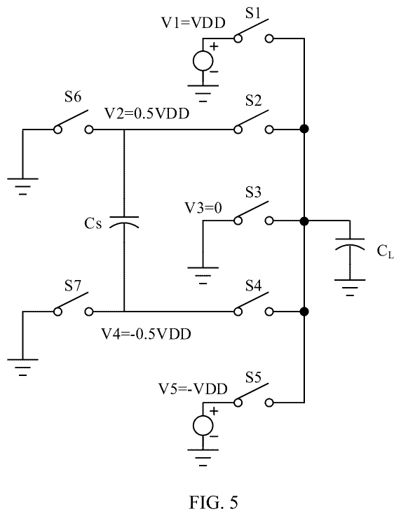

FIG. 5 shows another drive circuit for generating a step wave drive signal. The circuit architecture of the drive circuit in FIG. 5 is basically similar to that in FIG. 3. Switches S6 and S7 and an energy storage capacitor Cs in FIG. 5 are used to replace the two energy storage capacitors Cs1 and Cs2 in FIG. 3. The S2 and S7 are switched on simultaneously, the S4 and S6 are switched on simultaneously, and the capacitor Cs is fully utilized to establish equilibrium voltages V2=0.5×VDD and V4=−0.5×VDD.

The drive circuits shown in FIGS. 3-5 are generally applied to low-voltage domains, such as a voltage range of 3V-5V, such as VDD=5V.

An amplitude of a signal that can be provided by the drive circuit of the pen tip electrode of the active pen determines the detection accuracy of the touch screen on the capacitance change of its touch electrode, and the power consumption generated by itself is also the main source of losses of the drive circuit. In a scenario of a portable device such as the active pen, the voltage amplitude of the drive signal needs to be increased to improve a signal-to-noise ratio (SNR) of the signal detected by the touch screen. Moreover, the power consumption needs to be minimized to extend the working time of the active pen. These are key indicators of an integrated circuit chip (IC) a high-end active pen.

To this end, the present disclosure further provides a drive circuit that charges or discharges the load sequentially by arranging at least one voltage generation circuit and at least one energy storage element in the drive circuit, so that the voltage of the load varies stepwise after each charge phase or discharge phase, thereby increasing the amplitude of the signal outputted from the drive circuit without increasing the power consumption.

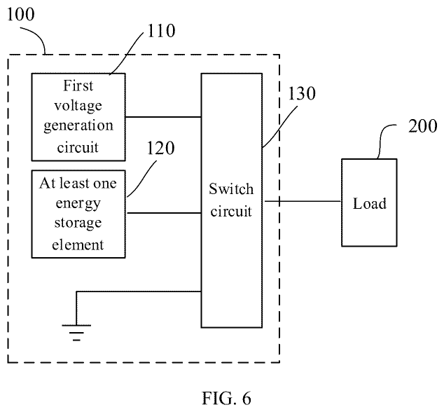

FIG. 6 shows a schematic block diagram of a drive circuit 100 in an embodiment of the present disclosure. The drive circuit 100 shown in FIG. 6 can be used as a drive circuit for a capacitive load 200. For example, the drive circuit 100 can be applied to an active pen as a drive circuit of a pen tip electrode of the active pen. For another example, the drive circuit 100 can be applied to a touch panel as a drive circuit for a touch electrode in the touch panel.

As shown in FIG. 6, the drive circuit 100 comprises a first voltage generation circuit 110, at least one energy storage element 120, and a switch circuit 130, the first voltage generation circuit 110 and the at least one energy storage element 120 are connected to a load 200 through the switch circuit 130, and the first voltage generation circuit 110 is configured to output a first power supply voltage.

For example, one terminal of each of the first voltage generation circuit 110 and the at least one energy storage element 120 is grounded, and the other terminal is connected to the load 200, which is equivalent to a parallel connection between the first voltage generation circuit 110 and the at least one energy storage element 120.

Each drive cycle may include, for example, a first phase, a second phase, a third phase, and a fourth phase, wherein the switch circuit 130 is configured to: control the first voltage generation circuit 110 to charge the load 200 in the first phase until a voltage of the load 200 reaches the first power supply voltage, control the load 200 to discharge to the at least one energy storage element 120 sequentially in the second phase, control the load 200 to discharge to ground in the third phase, and control the at least one energy storage element 120 to charge the load 200 sequentially in the fourth phase, so that the voltage of the load 200 rises and falls stepwise between different phases.

The number of energy storage elements 120 may be one, or may be a plural in number. When the energy storage elements 120 is plural in number, the second phase includes a plurality of sub-phases corresponding to the plurality of energy storage elements, wherein the load 200 discharges to a corresponding energy storage element 120 in each sub-phase; and similarly, the fourth phase also includes a plurality of sub-phases corresponding to the plurality of energy storage elements, wherein a corresponding energy storage element 120 charges the load 200 in each sub-phase.

In an embodiment of the present disclosure, the first voltage generation circuit 110 and the at least one energy storage element 120 are arranged in the drive circuit 100, to charge or discharge the load 200 sequentially, so that the voltage of the load 200 varies stepwise after each charge stage or discharge stage. Compared with the case where the drive circuit 100 directly outputs a square wave signal, the stepwise rise or fall of the voltage can effectively reduce power consumption of the power source, and increase an amplitude of a signal outputted from the drive circuit 100 without increasing the power consumption.

It should be noted that the charge and discharge in the embodiment of the present disclosure are described from the perspective of the load 200, wherein the charging the load 200 by a module means that charges of the module are transferred to the load 200; and the discharging the load 200 to a module means that charges of the load 200 are transferred to the module.

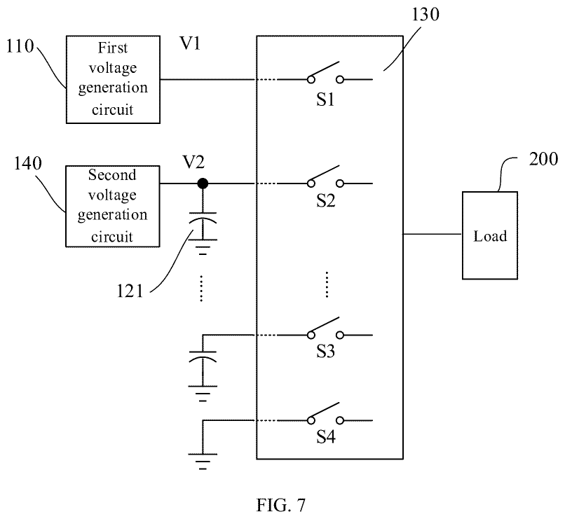

In some embodiments, for the drive circuit 100 as shown in FIG. 7, the drive circuit 100 further comprises a second voltage generation circuit 140, the second voltage generation circuit 140 is connected in parallel with a first energy storage element 121 among the at least one energy storage element 120, the second voltage generation circuit 140 is configured to output a second power supply voltage, and the second power supply voltage is smaller than the first power supply voltage.

In this case, in the above second phase, the load 200 discharges to the first energy storage element 121 until the voltage of the load 200 reaches the second power supply voltage; and in the above fourth phase, the first energy storage element 121 charges the load 200 until the voltage of the load 200 reaches the second power supply voltage.

Since the second voltage generation circuit 140 in parallel with the first energy storage element 121 is arranged in the drive circuit 100, the second voltage generation circuit 140 is equivalent to a bias power source, and can bias the voltage of the load 200 to the second power supply voltage during charge transfer between the first energy storage element 121 and the load 200, thereby effectively regulating a voltage value corresponding to each step.

For example, the second supply voltage may be set to half of the first supply voltage. In this case, the voltage of the load 200 is half of the first power supply voltage outputted from the first voltage generation circuit 110 in a stage of discharging the load 200 to the first energy storage element 121 in the second phase and in a stage of charging the load 200 by the first energy storage element 121 in the fourth phase.

Due to the existence of the second voltage generation circuit 140, the load 200 discharges to the second energy storage element 122 in the second phase until the voltage of the load 200 reaches half of the second power supply voltage outputted from the second voltage generation circuit 140, and the second energy storage element 122 charges the load 200 in the fourth phase until the voltage of the load 200 reaches half of the second power supply voltage.

The first voltage generation circuit 110 and the second voltage generation circuit 140 are configured to provide a DC power source. For example, the first voltage generation circuit 110 and the second voltage generation circuit 140 may be a charge pump circuit and a boost circuit, respectively. The charge pump circuit cooperates with the boost circuit to control the voltage value corresponding to each step, which is conducive to improving the efficiency of the first voltage generation circuit 110 and the second voltage generation circuit 140.

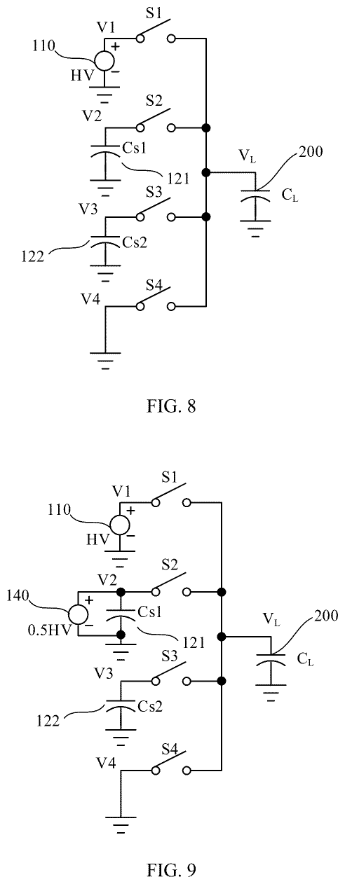

As an example, the drive circuit 100 in an embodiment of the present disclosure will be described in detail below with reference to FIGS. 8-11.

In FIGS. 8 and 9, the number of energy storage elements 120 is 2 as an example. As shown in FIGS. 8 and 9, the drive circuit 100 comprises a first energy storage element 121 and a second energy storage element 122, and the switch circuit 130 is specifically configured to control the load 200 to discharge to the first energy storage element 121 and the second energy storage element 122 sequentially in the second phase, and control the second energy storage element 122 and the first energy storage element 121 to sequentially charge the load 200 in the fourth phase.

That is to say, the second phase includes a first sub-phase φ2 and a second sub-phase φ3 respectively. In the first sub-phase φ2, the load 200 discharges to the first energy storage element 121, and in the second sub-phase φ3, the load 200 discharges to the second energy storage element 122. Similarly, the fourth phase includes a third sub-phase φ5 and a fourth sub-phase φ6. In the third sub-phase φ5, the first energy storage element 121 charges the load 200, and in the fourth sub-phase φ6, the second energy storage element 122 charges the load 200.

As shown in FIGS. 8 and 9, the switch circuit 130 comprises a first switch unit S1, a second switch unit S2, a third switch unit S3, and a fourth switch unit S4. The first switch unit S1 is connected between the first voltage generation circuit 110 and the load 200, the second switch unit S2 is connected between the first energy storage element 121 and the load 200, the third switch unit S3 is connected between the second energy storage element 122 and the load 200, and the fourth switch unit S4 is connected between the load 200 and ground.

In FIGS. 8 and 9, the at least one energy storage element 120 is an energy storage capacitor as an example, which can be easily implemented and has a simple structure, and may, in a practical application, be replaced with other energy storage elements or combinations thereof, to implement the charge storage function. In FIG. 9, the first energy storage element 121 in parallel with the second voltage generation circuit 140 can further multiplex a voltage stabilizing capacitor of the second voltage generation circuit 140, thereby reducing the costs.

The conduction sequence of each switch circuit 130 among the switch circuits 130 is reasonably controlled, thereby respectively implementing the processes of charging the load 200 by the first voltage generation circuit 110, discharging the load 200 to the at least one energy storage element 120, discharging the load 200 to ground, and charging the load 200 by the at least one energy storage element 120 sequentially in different phases, and obtaining a stepwise rising and falling drive voltage.

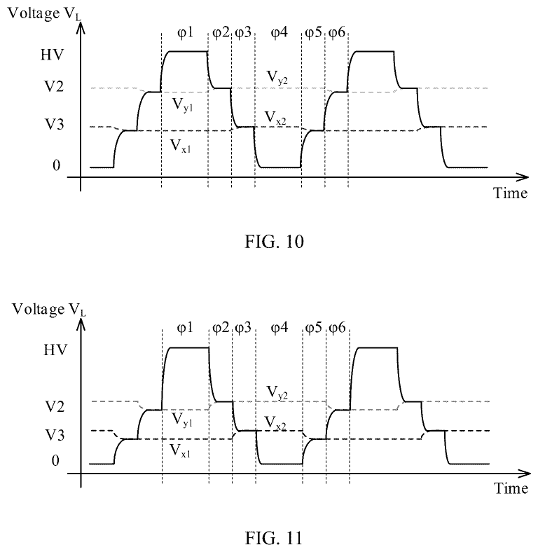

For example, as shown in FIGS. 10 and 11, each drive cycle includes 6 phases, namely a first phase φ1, a first sub-phase φ2, a second sub-phase φ3, a third phase φ4, a third sub-phase φ5, and a fourth sub-phase φ6, which are referred to as phase φ1, phase φ2, phase φ3, phase φ4, phase φ5, and phase φ6 below, respectively. The first sub-phase φ2 and the second sub-phase φ3 form a second phase, that is, a phase of discharging the load 200; and the third sub-phase φ5 and the fourth sub-phase φ6 form a fourth phase, that is, a phase of charging the load 200 by the at least one energy storage element 120.

For ease of description, voltage V_{L} of the load 200 in different phases is represented as voltage V1, voltage V2, voltage V3, and voltage V4 respectively. In the first phase φ1, the voltage V_{L} of the load 200 is represented as V1, which may change with the charging and discharging process between the first voltage generation circuit 110 and the load 200; in the first sub-phase φ2 and the fourth sub-phase φ6, the voltage V_{L} of the load 200 is represented as V2, which may vary with the charging and discharging process between the first energy storage element 121 and the load 200; in the second sub-phase φ3 and the third sub-phase φ5, the voltage V_{L} of the load 200 is represented as V3, which may change with the charging and discharging process between the second energy storage element 122 and the load 200; and in the third phase φ4, the voltage V_{L} of the load 200 is represented as V4, which may change with the process of discharging the load 200 to ground.

In the first phase φ1, the first switch unit S1 is switched on, the first voltage generation circuit 110 charges the load 200, and the voltage V1 of the load 200 rises from V_{y1} to HV. Here, it is assumed that the first power supply voltage outputted from the first voltage generation circuit 110 is a high-voltage power supply signal HV, for example, the voltage range is between 40V and 60V;
in the first sub-phase φ2, the second switch unit S2 is switched on, the load 200 discharges to the first energy storage element 121, which is equivalent to recycling a part of charges, and the voltage V2 of the load 200 varies from HV to V_{y2};
in the second sub-phase φ3, the third switch unit S3 is switched on, the load 200 discharges to the second energy storage element 122, which is equivalent to recycling a part of charges, and the voltage V3 of the load 200 varies from V_{y2} to Vₓ₂;
in the third phase φ4, the fourth switch unit S4 is switched on, the load 200 discharges to ground, and the voltage V4 of the load 200 varies from Vₓ₂ to a ground voltage, such as 0;
in the third sub-phase φ5, the third switch unit S3 is switched on, the second energy storage element 122 charges the load 200, and the voltage V3 of the load 200 varies from the ground voltage, such as 0, to Vₓ₁; and
in the fourth sub-phase φ6, the second switch unit S2 is switched on, the first energy storage element 121 charges the load 200, and the voltage V2 of the load 200 varies from Vₓ₁ to V_{y1}.

In fact, even if the second voltage generation circuit 140 is not provided, initial charges on the first energy storage element 121 and the second energy storage element 122 are zero, and equilibrium voltages thereof can still be naturally established by continuously charging and discharging to reach a steady state according to the above processes. Finally, the voltages on the first energy storage element 121 and the second energy storage element 122 will be stabilized near a voltage value, which may be calculated, for example, in the following manner.

First, without considering the second voltage generation circuit 140, for example, as shown in FIG. 8, the voltages on the first energy storage element 121 and the second energy storage element 122 are analyzed sequentially.

After the phase φ1 ends, the first switch unit S1 is switched off, and in this case, the voltage on the load 200 is HV. When the phase 2 starts, the voltage V_{y1} in the previous phase φ6 is maintained on the first energy storage element 121. When the second switch unit S2 is switched on, charges on the first energy storage element 121 and the load 200 are redistributed between each other to establish a new voltage V_{y2}. According to the law of charge conservation, the following formula can be obtained:

$${C}_{L} \times H V + {C}_{s 1} \times {V}_{y 1} = ( {C}_{L} + {C}_{s 1} ) \times {V}_{y 2} ; \qquad ( 1 )$$

wherein C_{L} is a capacitance value of the load 200, and Cₛ₁ is a capacitance value of the first energy storage element 121.

After the phase φ2 ends, the second switch unit S2 is switched off, and in this case, the voltage on the load 200 is V_{y2}. When the phase φ3 starts, the voltage Vₓ₁ in the previous phase φ5 is maintained on the second energy storage element 122. When the third switch unit S3 is switched on, charges on the second energy storage element 122 and the load 200 are redistributed between each other to establish a new voltage Vₓ₂. According to the law of charge conservation, the following formula can be obtained:

$${C}_{L} \times {V}_{y 2} + {C}_{s 2} \times {V}_{x 1} = ( {C}_{L} + {C}_{s 2} ) \times {V}_{x 2} ; \qquad ( 2 )$$

wherein Cₛ₂ is a capacitance value of the second energy storage element 122.

After the phase φ2 ends, the second switch unit S2 is switched off. In this case, the voltage on the first energy storage element 121 is V_{y2}. When the phase φ6 starts, the voltage on the C_{L} is Vₓ₁. When the second switch unit S2 is switched on, charges on the first energy storage element 121 and the load 200 are redistributed between each other to establish a new voltage V_{y1}. According to the law of charge conservation, the following formula can be obtained:

$${C}_{L} \times {V}_{x 1} + {C}_{s 1} \times {V}_{y 2} = ( {C}_{L} + {C}_{s 1} ) \times {V}_{y 1} . \qquad ( 3 )$$

After the phase φ3 ends, the third switch unit S3 is switched off, and in this case, the voltage on the second energy storage element 122 is Vₓ₂. When the phase φ5 starts, the voltage on the load 200 is 0, and no charges are stored thereon. When the third switch unit S3 is switched on, the charges on the second energy storage element 122 are redistributed between the second energy storage element 122 and the load 200, to establish a new voltage Vₓ₁. According to the law of charge conservation, the following formula can be obtained:

$${C}_{L} \times 0 + {C}_{s 2} \times {V}_{x 2} = ( {C}_{L} + {C}_{s 2} ) \times {V}_{x 1} . \qquad ( 4 )$$

It is assumed that the capacitance Cₛ₁ of the first energy storage element 121 is equal to the capacitance Cₛ₂ of the second energy storage element 122, that is, Cₛ₁=Cₛ₂=Cₛ, based on the above formulas (1)-(4), namely:

$${C}_{L} \times H V + {C}_{s 1} \times {V}_{y 1} = ( {C}_{L} + {C}_{s 1} ) \times {V}_{y 2} ; \qquad ( 1 )$$

$${C}_{L} \times {V}_{y 2} + {C}_{s 2} \times {V}_{x 1} = ( {C}_{L} + {C}_{s 2} ) \times {V}_{x 2} ; \qquad ( 2 )$$

$${C}_{L} \times {V}_{x 1} + {C}_{s 1} \times {V}_{y 2} = ( {C}_{L} + {C}_{s 1} ) \times {V}_{y 1} ; and \qquad ( 3 )$$

$${C}_{L} \times 0 + {C}_{s 2} \times {V}_{x 2} = ( {C}_{L} + {C}_{s 2} ) \times {V}_{x 1} ; \qquad ( 4 )$$

Vₓ₁, Vₓ₂, V_{y1}, and V_{y2} can be obtained as follows:

$${V}_{x 1} = ( {C}_{s} \times H V ) / ( {C}_{L} + 3 \times {C}_{s} ) ; \qquad ( 5 )$$

$${V}_{x 2} = ( {C}_{L} \times H V + {C}_{s} \times H V ) / ( {C}_{L} + 3 \times {C}_{s} ) ; \qquad ( 6 )$$

$${V}_{y 1} = ( 2 \times {C}_{s} \times H V ) / ( {C}_{L} + 3 \times {C}_{s} ) ; and \qquad ( 7 )$$

$${V}_{y 2} = ( {C}_{L} \times H V + 2 \times {C}_{s} \times H V ) / ( {C}_{L} + 3 \times {C}_{s} ) . \qquad ( 8 )$$

When Cₛ>>C_{L}, Vₓ₁=Vₓ₂=HV/3, V_{y1}=V_{y2}=2×HV/3, that is, after equilibration, V2=2×HV/3 and V3=HV/3. When the second voltage generation circuit 140 is provided in a branch circuit where the first energy storage element 121 is located, the second voltage generation circuit 140 is configured to provide a second power supply voltage. For example, as shown in FIG. 9, assuming that the second power supply voltage is half of the first power supply voltage, i.e., 0.5×HV, the voltage V2 is biased to 0.5×HV. However, the voltage V3 is still generated by charge-discharge equilibrium in a driving process. Based on similar analysis, the equilibrium voltage can be obtained as V3=0.25×HV, that is, V3=V2/2.

When the second voltage generation circuit 140 is not provided, for example, as shown in FIG. 10, the voltage values corresponding to the steps are 0, HV/3, 2×HV/3, and HV, respectively. The first voltage generation circuit 110 consumes energy only in the phase φ1. Therefore, when the capacitance value of the load 200 is C_{L} and the frequency of the drive signal is f, the power P₁ consumed by the first voltage generation circuit 110 is:

$${P}_{1} = H V \times H V / 3 \times {C}_{L} \times f = H {V}^{2} \times {C}_{L} \times f / 3 . \qquad ( 9 )$$

It is understandable that when the power is calculated, since the power is a product of voltage and average current, the average current is equal to a ratio of charge quantity to time, that is, a product of the charge quantity and the frequency f, and the charge quantity is equal to a product of capacitance value and voltage variation quantity, the power can be obtained to be equal to a product of voltage in a current phase, voltage variation quantity between the current phase and a previous phase, capacitance, and the frequency f.

To maintain high efficiency as much as possible to obtain a higher voltage V1, for example, as shown in FIG. 11, the voltage V2 provided by the second voltage generation circuit 140, such as a boost circuit, can be used to obtain the voltage V1 through the first voltage generation circuit 110, such as a charge pump circuit. Therefore, based on the above analysis, the voltage values corresponding to all the steps are 0, HV/4, HV/2, and HV, respectively. The voltage value HV/4 corresponding to the step caused by the second energy storage element 122 is equilibrated by charging and discharging between itself and the load 200. Except for energy consumption in an establishment process of the initial drive cycle, when an equilibrated voltage is established and stabilized, in the drive cycle thereafter, a waveform step outputting the HV/4 voltage reaches dynamic equilibrium relying on the “charge-discharge” between the second energy storage element 122 and the load 200, and no longer consumes charges from a power source to maintain the HV/4 voltage.

At a step of the voltage value HV/2, in the phase φ6 corresponding to a rising edge, the second voltage generation circuit 140 charges the voltage on the load 200 from HV/4 to HV/2, and the power consumption thereof is:

$${P}_{V 2\_ 1} = HV / 2 \times H V / 4 \times {C}_{L} \times f = H {V}^{2} / 8 \times {C}_{L} \times f . \qquad ( 10 )$$

In the phase φ2 corresponding to a falling edge, the voltage on the load 200 is HV, and the second voltage generation circuit 140 discharges the load 200 from the voltage of HV to HV/2, or charges the first energy storage element 121, and recycles corresponding charges on the first energy storage element 121. The recycled charges are used to be discharged and outputted in a phase corresponding to a rising edge of a next drive cycle. Specifically, power consumption generated by the second voltage generation circuit 140 to maintain boosting can be reduced. As an example, the Boost circuit is the second voltage generation circuit 140. To generate a high voltage to drive the load, the Boost circuit needs to continuously pump charges to the voltage stabilizing capacitor, that is, the first energy storage element 121 at a certain frequency. This process generates power consumption and is positively correlated with the number of times or frequency of pumping. In an embodiment of the present disclosure, since charges are recycled to the first energy storage element 121 for supplement, the second voltage generation circuit 140 can reduce the frequency or number of times of pumping charges through its own feedback, thereby reducing power consumption. Therefore, it is equivalent to reducing the power consumption of the entire cycle of the second voltage generation circuit 140. The recycled power is:

$${P}_{V 2\_ 2} = - H V / 2 \times H V / 2 \times {C}_{L} \times f = - H {V}^{2} / 4 \times {C}_{L} \times f ; \qquad ( 11 )$$

wherein the negative sign “−” means that the second voltage generation circuit 140 does not consume energy, and the first energy storage element 121 recycles charges.

Based on the formulas (10) and (11), the total power consumption of the second voltage generation circuit 140 can be obtained as:

$${P}_{V 2} = {P}_{V 2\_ 1} + {P}_{V 2\_ 2} = - H {V}^{2} / 8 \times C L \times f . \qquad ( 12 )$$

The first voltage generation circuit 110 only consumes power in the phase φ1 corresponding to a rising edge, its output charges the load 200 from the voltage of HV/2 to HV, and its power consumption is P_{V1}=HV×HV/2×CL×f=HV²/2×C_{L}×f. Therefore, the total power consumption of the first voltage generation circuit 110 and the second voltage generation circuit 140 is:

$${P}_{total} = {P}_{V 1} + {P}_{V 2} = 3 \times H {V}^{2} / 8 \times {C}_{L} \times f . \qquad ( 13 )$$

The energy consumption mentioned above can be understood as a process of outputting charges to the outside. This process requires power consumption.

It can be seen that the drive circuit 100 comprises the first voltage generation circuit 110, the first energy storage element 121, the second energy storage element 122, and a ground voltage that are connected to the load 200 respectively, forming four corresponding branch circuits, the second voltage generation circuit 140 is provided in a branch circuit where the first energy storage element 121 is located, and the four branch circuits are switched on alternately, thereby obtaining a drive voltage with four steps in each of voltage rising stages and voltage falling stages, wherein the voltages corresponding to the four steps are the first power supply voltage HV, the second power supply voltage HV/2, half of the second power supply voltage HV/2, and the ground voltage respectively.

Under equal conditions, compared with a conventional drive circuit that outputs a square wave signal, the power consumed by the power source to output a square wave signal of a same amplitude is P=HV²×C_{L}×f. As can be seen from comparison with the formula (13), the power consumption of the drive circuit 100 shown in FIG. 9 is only ⅜ of the power consumption of the drive circuit that outputs the square wave signal. Considering the losses of power conversion efficiency, the drive circuit 100 shown in FIG. 9 can reduce at least 50% of the power consumption.

In addition, there is a certain relationship between the efficiency and the output voltage of the boost circuit. Generally, the efficiency of the boost circuit decreases as the output voltage increases. This is because in a voltage conversion process of the boost circuit, the longer time it takes to transmit the current to the load 200 through an inductor, the more the energy losses are. Therefore, a high output voltage requires more energy transfer, thereby reducing the efficiency of the boost circuit.

To implement the driving solution of the signal amplitude from 0 to HV, a first case is to output the voltage HV using only one boost circuit, that is, the first voltage generation circuit, as the power source. It is assumed that in this case, the efficiency of the first voltage generation circuit 110 is η1.

A second case is to first output the second power supply voltage, such as 0.5×HV, using a boost circuit, that is, the second voltage generation circuit 140, as a power source, and then obtain a high-voltage power source using a high-efficiency power conversion circuit such as a charge pump, that is, the first voltage generation circuit 110, to output the first power supply voltage, such as HV. Assuming that in this case, the efficiency of the second voltage generation circuit 140 is η2 and the efficiency of the first voltage generation circuit 110 is η3, in the process of obtaining the voltage HV through the second voltage generation circuit 140 and the first voltage generation circuit 110, the total efficiency is η2×13.

Generally, the efficiency of the charge pump, that is, η3, is generally above 90%, and may reach 95% under a heavy load; for the boost circuit, the efficiency η1 when outputting HV is not necessarily as high as the efficiency 12 when outputting the second power supply voltage such as 0.5HV. As mentioned above, the higher the output voltage is, the lower the power source efficiency is. Therefore, the efficiency η1 in the first case, for example, 70% η2-80% η2, is often not as high as the boosting efficiency η2×η3, for example, 90% η2-95% η2, in a second sub-segment in the second case.

In addition, the second voltage generation circuit 140 that outputs the second power supply voltage, such as 0.5 HV, is also more conductive to the selection of an electronic element such as a peripheral inductor or a diode of a chip from the perspectives of voltage resistance, cost, and encapsulation.

In addition, the second power supply voltage provided by the second voltage generation circuit 140 may also be set to a value other than 0.5HV. The first power supply voltage and the second power supply voltage may be set independently of each other, and do not necessarily have a constant multiple relationship. The second power supply voltage directly determines a voltage value corresponding to a step, that is, the waveform of the stepped drive voltage can be changed by regulating the magnitude of the second power supply voltage, and is strongly flexible.

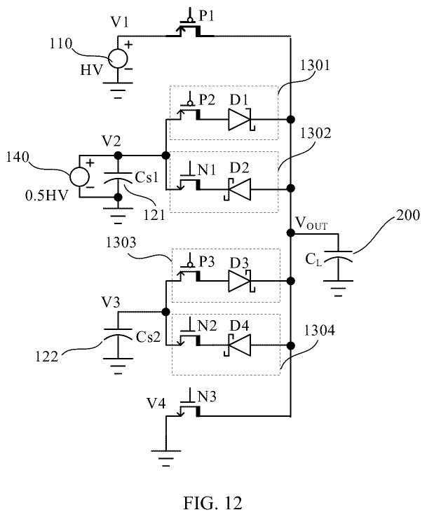

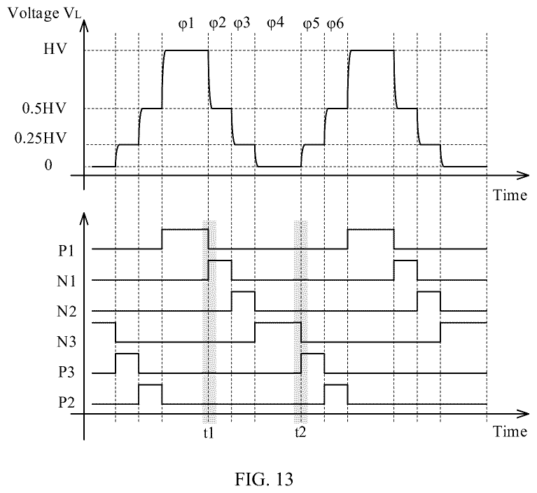

The specific structure of the switch circuit 130 of the drive circuit 100 is described in detail below with reference to FIGS. 12 and 13.

In some embodiments, a switch circuit 130 connected between the first voltage generation circuit 110 and the load 200 among the switch circuits 130 comprises a PMOS device; and a switch circuit 130 connected between each energy storage element and the load 200 among the switch circuits 130 comprises two groups of switches in parallel, wherein the first group of switches comprise a PMOS device and a diode in series, the second group of switches comprise an NMOS device and a diode in series, the diode in the first group of switches and the diode in the second group of switches have opposite conduction directions, and a switch circuit 130 connected between the load 200 and ground among the switch circuits 130 comprises an NMOS device.

The first group of switches can be configured, for example, to charge the load 200 by a corresponding energy storage element, and the second group of switches can be configured, for example, to discharge the load 200 to a corresponding energy storage element.

When applied to a low-voltage driving scenario, such as a scenario with a voltage range of 3.3V-5V, the PMOS device and the NMOS device may adopt low-voltage MOS devices; while when applied to a high-voltage driving scenario, such as a scenario with a voltage range of 40V-60V, the PMOS device may adopt a P-type LDMOS device, and the NMOS device may adopt an N-type LDMOS device.

The LDMOS device may be an asymmetric LDMOS device configured to implement unidirectional conduction.

For example, as shown in FIG. 12, the switch circuit 130 is implemented using a P-type laterally diffused metal oxide semiconductor (LDMOS) device and an N-type LDMOS device. In FIG. 10, as an example, the drive circuit 100 comprises a first energy storage element 121 and a second energy storage element 122, the first voltage generation circuit 110 outputs a first power supply voltage HV, and the second voltage generation circuit 140 outputs a second power supply voltage HV/2.

A PMOS device P1 is connected between the first voltage generation circuit 110 and the load 200, wherein the source electrode of the P1 is connected to the first voltage generation circuit 110, and the drain electrode of the P1 is connected to the load 200.

The first energy storage element 121 is connected to the load 200 through two groups of switches in parallel. The first group of switches 1301 comprise a PMOS device P2 and a diode D1 in series, the source electrode of the P2 is connected to the first energy storage element 121, and the drain electrode of the P2 is connected to the diode D1; while the second group of switches 1302 comprise an NMOS device N1 and a diode D2, the source electrode of the N1 is connected to the first energy storage element 121, and the drain electrode of the N1 is connected to the diode D2. The diode D1 and the diode D2 have opposite conduction directions, the conduction direction of the diode D1 is from the first energy storage element 121 to the load 200, and the conduction direction of the diode D2 is from the load 200 to the first energy storage element 121. In this way, a branch circuit corresponding to the first group of switches 1301 is a pure charging branch circuit of the load 200, and is configured to charge the load 200 by the first energy storage element 121, while a branch circuit corresponding to the second group of switches 1302 is a pure discharging branch circuit of the load 200, and is configured to discharge the load 200 to the first energy storage element 121.

The second energy storage element 122 is also connected to the load 200 through two groups of switches in parallel. The first group of switches 1303 comprise a PMOS device P3 and a diode D3 in series, the source electrode of the P3 is connected to the second energy storage element 122, and the drain electrode of the P3 is connected to the diode D3; while the second group of switches 1304 comprise an NMOS device N2 and a diode D4, the source electrode of the N2 is connected to the second energy storage element 122, and the drain electrode of the N2 is connected to the diode D4. The diode D3 and the diode D4 have opposite conduction directions, the conduction direction of the diode D3 is from the second energy storage element 122 to the load 200, and the conduction direction of the diode D4 is from the load 200 to the second energy storage element 122. In this way, a branch circuit corresponding to the first group of switches 1303 is a pure charging branch circuit of the load 200, and is configured to charge the load 200 by the second energy storage element 122, while a branch circuit corresponding to the second group of switches 1304 is a pure discharging branch circuit of the load 200, and is configured to discharge the load 200 to the second energy storage element 122.

An NMOS device N3 is connected between the ground voltage and the load 200, the source electrode of the N3 is connected to the ground voltage, and the drain electrode of the N3 is connected to the load 200.

In a high-voltage scenario, the above diodes D1, D2, D3 and D4 may be, for example, Schottky diodes with fast recovery speed and high voltage resistance, and of course, in a low-voltage scenario or other application scenarios, may be replaced with conventional PN diodes or some unidirectional conductive devices.

In FIG. 12, charging and discharging branch circuits of the first energy storage element 121 and the second energy storage element 122 isolate the branch circuits controlled by the second switch unit S2 and the third switch unit S3 shown in FIG. 4 into pure charging and pure discharging branch circuits controlled by the MOS devices P2, N1, P3 and N2 shown in FIG. 10 using unidirectional conductivity of a PN junction diode according to the charging and discharging processes. In this way, due to the existence of the diodes D1, D2, D3, and D4, even if branch circuits controlled by the PMOS device are switched on simultaneously, a branch circuit where the P1 is located will not form a high-voltage sink current on a branch circuit where the P2 is located, nor will the branch circuit where the P2 is located form a high-voltage sink current on a branch circuit where the P3 is located. Similarly, even if branch circuits controlled by the NMOS device are switched on simultaneously, a branch circuit where the N3 is located will not form a high-voltage sink current on a branch circuit where the N2 is located, nor will the branch circuit where the N2 is located form a high-voltage sink current on a branch circuit where the N1 is located. Therefore, in switch switching processes of N1→N2→N3 and P3→P2→P1, it is not necessary to design a dead time to prevent corresponding branch circuits from conducting each other, which will cause short circuits and abnormal driving operation.

For switch switching processes of P1→N1 and N3→P3, as shown in FIG. 13, it is necessary to set the dead time. That is to say, it is necessary to set the dead time t1 only during switching from the P1 to the N1, and set the dead time t2 during switching from the N3 to the P3, thereby simplifying the complexity of the switching logic circuit.

As shown in FIGS. 12 and 13, when the drive circuit 100 is working normally, the MOS devices are switched on alternately in the following sequence: P1→N1→N2→N3→P3→P2→P₁→ . . . , thereby switching on corresponding branch circuits individually, and outputting a stepped drive voltage: HV→HV/2→HV/4→0→HV/4→HV/2→HV→ . . . . The specific working process is as follows:
in the first phase φ1, gate voltage of the PLDMOS device P1 is pulled down to below HV−|Vthp|, the P1 is switched on, other MOS devices are switched off, the first voltage generation circuit 110 charges the load 200, and the voltage V1 of the load 200 rises from HV/2 to HV;
in the first sub-phase φ2, gate voltage of the NLDMOS device N1 is pulled up to above 0.5×HV+Vthn, the N1 is switched on, other MOS devices are switched off, and the load 200 discharges to the first energy storage element 121, which is equivalent to recycling a part of charges, and the voltage V2 of the load 200 varies from HV to 0.5×HV;
in the second sub-phase φ3, gate voltage of the NLDMOS device N2 is pulled up to above 0.25×HV+Vthn, the N2 is switched on, other MOS devices are switched off, and the load 200 discharges to the second energy storage element 122, which is equivalent to recycling a part of charges, and the voltage V3 of the load 200 varies from 0.5×HV to 0.25×HV;
in the third phase φ4, gate voltage of the NLDMOS device N3 is pulled up to above Vthn, the N3 is switched on, other MOS devices are switched off, the load 200 discharges to ground, and the voltage V4 of the load 200 varies from 0.25×HV to the ground voltage, such as 0;
in the third sub-phase φ5, gate voltage of the PLDMOS device P3 is pulled down to below 0.25×HV−|Vthp|, the P3 is switched on, other MOS devices are switched off, the second energy storage element 122 charges the load 200, and the voltage V3 of the load 200 varies from the ground voltage, such as 0, to 0.25×HV; and
in the fourth sub-phase φ6, gate voltage of the PLDMOS device P2 is pulled down to below 0.5×HV−|Vthp|, the P2 is switched on, other MOS devices are switched off, the first energy storage element 121 charges the load 200, and the voltage V2 of the load 200 varies from 0.25×HV to 0.5×HV.

Vthp and Vthn are threshold voltages of the P-type LDMOS device and the N-type LDMOS device respectively, gate voltage of the P-type LDMOS device is pulled down to below source voltage by more than one threshold voltage, and gate voltage of the N-type LDMOS device is pulled up to above source voltage by more than one threshold voltage, so that the MOS device can be fully switched on. The larger the difference between the gate voltage and the source voltage is, the better the conductivity is. However, it should be noted that the voltage resistance range of the gate electrode and the source electrode of the MOS device should not be exceeded, and otherwise, the device breakdown and damage will be caused.

Based on the drive circuit and its switching sequence shown in FIGS. 12 and 13, a dead time for switch switching is set between the first phase φ1 and the first sub-phase φ2, no dead time is set between the first sub-phase φ2 and the second sub-phase φ3, and between the second sub-phase φ3 and the third phase φ4, a dead time is set between the third phase φ4 and the third sub-phase φ5, and no dead time is set between the third sub-phase φ5 and the fourth sub-phase φ6. Therefore, the above solution greatly simplifies the complexity of the switching control logic.

In some embodiments, a branch circuit where at least a part of energy storage elements among the at least one energy storage element 120 are located may be configured to have enabling and disabling functions. When a branch circuit is enabled, the branch circuit is configured to charge and discharge the load 200. When a branch circuit is disabled, the branch circuit is prohibited from charging and discharging the load 200. Some branch circuits are configured to be enabled or disabled, thereby flexibly controlling the number of the steps s of the drive voltage.

For example, the branch circuit where the first energy storage element 121 is located can be configured to have an enabling or disabling function. When the branch circuit where the first energy storage element 121 is located is disabled, the drive circuit 100 only comprises several remaining branch circuits to generate the drive voltage.

For another example, a branch circuit where the second energy storage element 122 is located can be configured to have an enabling or disabling function. When the branch circuit where the second energy storage element 122 is located is disabled, the drive circuit 100 only comprises several remaining branch circuits to generate the drive voltage.

In this way, in different application scenarios, an enabled branch circuit in the drive circuit 100 can be selected to output a step wave voltage with a desirable number of steps and desirable voltage values.

The present disclosure further provides an active pen/stylus, comprising the drive circuit 100 according to any one of the above embodiments and a pen tip electrode connected to the drive circuit 100, wherein the drive circuit 100 is configured to provide a drive voltage to the pen tip electrode.

The present disclosure further provides a touch panel, comprising the drive circuit 100 according to any one of the above embodiments, and a touch electrode such as a TX electrode connected to the drive circuit 100, wherein the drive circuit 100 is configured to provide a drive voltage to the touch electrode.

It should be noted that the embodiments described in the present disclosure and/or the technical features in the embodiments may be combined with each other in any way in the case of no conflict, and the combined technical solutions should also be encompassed within the scope of protection of the present disclosure.

The system, the apparatus, and the method disclosed in the embodiments of the present disclosure may be implemented in other ways. For example, some features of the method embodiments described above may be neglected, or may not be implemented. The above-described apparatus embodiments are merely illustrative, the division of the units is only a logical function division, other division manners may be available during actual implementations, and a plurality of units or components may be combined or may be integrated into another system. In addition, the coupling between the units or the coupling between the components may be direct coupling or may be indirect coupling, and the above-mentioned coupling includes electrical connection, mechanical connection, or other forms of connection.

Those skilled in the art can clearly understand that, for convenience and simplicity of description, corresponding processes and technical effects in the above method embodiments may be referred to for specific working process of the apparatus and the device described above and technical effects thereof, which will not be repeated here.

It should be understood that the specific examples in the embodiments of the present disclosure are provided only to help those skilled in the art to better understand the embodiments of the present disclosure, rather than limiting the scope of the embodiments of the present disclosure. Those skilled in the art may make various improvements and modifications on the basis of the above embodiments, and these improvements or modifications are all encompassed within the scope of protection of the present disclosure.

While the above description merely provides specific embodiments of the present disclosure, the scope of protection of the present disclosure is not limited to the specific embodiments. Any person skilled in the art can easily conceive of alterations or replacements within the technical scope disclosed in the present disclosure. All these alterations or replacements should be encompassed within the scope of protection of the present disclosure. Therefore, the scope of protection of the present disclosure should be determined by the scope of protection of the claims.

1. A drive circuit, configured to provide a drive voltage to a capacitive load, and comprising a first voltage generation circuit, at least one energy storage element, and a switch circuit, wherein the first voltage generation circuit and the at least one energy storage element are connected to the load through the switch circuit, the first voltage generation circuit is configured to output a first power supply voltage, and
the switch circuit is configured to control the first voltage generation circuit to charge the load in a first phase until a voltage of the load reaches the first power supply voltage, control the load to discharge to the at least one energy storage element sequentially in a second phase, control the load to discharge to ground in a third phase, and control the at least one energy storage element to charge the load sequentially in a fourth phase, so that the voltage of the load rises and falls stepwise between different phases.

2. The drive circuit according to claim 1, wherein the drive circuit further comprises a second voltage generation circuit, the second voltage generation circuit is connected in parallel with a first energy storage element among the at least one energy storage element, the second voltage generation circuit is configured to output a second power supply voltage, and the second power supply voltage is smaller than the first power supply voltage,
wherein, in the second phase, the load discharges to the first energy storage element until the voltage of the load reaches the second power supply voltage, and in the fourth phase, the first energy storage element charges the load until the voltage of the load reaches the second power supply voltage.

3. The drive circuit according to claim 2, wherein the at least one energy storage element further comprises a second energy storage element, and the switch circuit is specifically configured to control the load to discharge to the first energy storage element and the second energy storage element sequentially in the second phase, and control the second energy storage element and the first energy storage element to sequentially charge the load in the fourth phase, wherein, in the second phase, the load discharges to the second energy storage element until the voltage of the load reaches half of the second power supply voltage, and in the fourth phase, the second energy storage element charges the load until the voltage of the load reaches half of the second power supply voltage.

4. The drive circuit according to claim 3, wherein the switch circuit comprises a first switch unit, a second switch unit, a third switch unit, and a fourth switch unit, the first switch unit is connected between the first voltage generation circuit and the load, the second switch unit is connected between the first energy storage element and the load, the third switch unit is connected between the second energy storage element and the load, and the fourth switch unit is connected between the load and ground,
the first switch unit is configured to be switched on in the first phase, so that the first voltage generation circuit charges the load until the voltage of the load reaches the first power supply voltage,
the second switch unit is configured to be switched on in a first sub-phase of the second phase, to discharge the load to the first energy storage element until the voltage of the load reaches the second power supply voltage,
the third switch unit is configured to be switched on in a second sub-phase of the second phase, to discharge the load to the second energy storage element until the voltage of the load reaches half of the second power supply voltage,
the fourth switch unit is configured to be switched on in the third phase, to discharge the load to ground until the voltage of the load reaches a ground voltage,
the third switch unit is further configured to be switched on in a third sub-phase of the fourth phase, so that the second energy storage element charges the load until the voltage of the load reaches half of the second power supply voltage, and
the second switch unit is further configured to be switched on in a fourth sub-phase of the fourth phase, so that the first energy storage element charges the load until the voltage of the load reaches the second power supply voltage.

5. The drive circuit according to claim 1, wherein
a switch unit connected between the first voltage generation circuit and the load in the switch circuit comprises a PMOS device,
a switch unit connected between each energy storage element and the load in the switch circuit comprises a first group of switches and a second group of switches in parallel, wherein the first group of switches comprise a PMOS device and a diode in series, the second group of switches comprise an NMOS device and a diode in series, and the diode in the first group of switches and the diode in the second group of switches have opposite conduction directions, and
a switch unit connected between the load and ground in the switch circuit comprises an NMOS device.

6. The drive circuit according to claim 5, wherein the first group of switches is configured to charge the load by the corresponding energy storage element, and the second group of switches is configured to discharge the load to the corresponding energy storage element.

7. The drive circuit according to claim 5, wherein the PMOS device is a P-type LDMOS device, and the NMOS device is an N-type LDMOS device.

8. The drive circuit according to claim 5, wherein a dead time for switch switching is set between the first phase and the second phase, the dead time is not set between at least one sub-phase in the second phase for discharging the load to the at least one energy storage element and between the second phase and the third phase, the dead time is set between the third phase and the fourth phase, and the dead time is not set between at least one sub-phase in the fourth phase for charging the load by the at least one energy storage element.

9. The drive circuit according to claim 2, wherein the first voltage generation circuit is a charge pump circuit, and the second voltage generation circuit is a boost circuit.

10. The drive circuit according to claim 2, wherein the energy storage element is an energy storage capacitor, and a voltage stabilizing capacitor of the second voltage generation circuit is multiplexed as the first energy storage element in parallel with the second voltage generation circuit.

11. The drive circuit according to claim 2, wherein the second power supply voltage is half of the first power supply voltage.

12. The drive circuit according to claim 1, wherein a branch circuit where at least part of the at least one energy storage element is located is configured to have enabling and disabling functions.

13. The drive circuit according to claim 1, wherein the load is a pen tip electrode of a capacitive active pen, or the load is a touch electrode in a touch panel.

14. An active pen, comprising a drive circuit and a pen tip electrode connected to the drive circuit, wherein the drive circuit is configured to provide a drive voltage to the pen tip electrode, the drive circuit comprising:
a first voltage generation circuit, at least one energy storage element, and a switch circuit, wherein the first voltage generation circuit and the at least one energy storage element are connected to the load through the switch circuit, the first voltage generation circuit is configured to output a first power supply voltage, and
the switch circuit is configured to control the first voltage generation circuit to charge the load in a first phase until a voltage of the load reaches the first power supply voltage, control the load to discharge to the at least one energy storage element sequentially in a second phase, control the load to discharge to ground in a third phase, and control the at least one energy storage element to charge the load sequentially in a fourth phase, so that the voltage of the load rises and falls stepwise between different phases.

15. The active pen according to claim 14, wherein the drive circuit further comprises a second voltage generation circuit, the second voltage generation circuit is connected in parallel with a first energy storage element among the at least one energy storage element, the second voltage generation circuit is configured to output a second power supply voltage, and the second power supply voltage is smaller than the first power supply voltage,
wherein, in the second phase, the load discharges to the first energy storage element until the voltage of the load reaches the second power supply voltage, and in the fourth phase, the first energy storage element charges the load until the voltage of the load reaches the second power supply voltage.

16. The active pen according to claim 15, wherein the at least one energy storage element further comprises a second energy storage element, and the switch circuit is specifically configured to control the load to discharge to the first energy storage element and the second energy storage element sequentially in the second phase, and control the second energy storage element and the first energy storage element to sequentially charge the load in the fourth phase,
wherein, in the second phase, the load discharges to the second energy storage element until the voltage of the load reaches half of the second power supply voltage, and in the fourth phase, the second energy storage element charges the load until the voltage of the load reaches half of the second power supply voltage.

17. The active pen according to claim 16, wherein the switch circuit comprises a first switch unit, a second switch unit, a third switch unit, and a fourth switch unit, the first switch unit is connected between the first voltage generation circuit and the load, the second switch unit is connected between the first energy storage element and the load, the third switch unit is connected between the second energy storage element and the load, and the fourth switch unit is connected between the load and ground,
the first switch unit is configured to be switched on in the first phase, so that the first voltage generation circuit charges the load until the voltage of the load reaches the first power supply voltage,
the second switch unit is configured to be switched on in a first sub-phase of the second phase, to discharge the load to the first energy storage element until the voltage of the load reaches the second power supply voltage,
the third switch unit is configured to be switched on in a second sub-phase of the second phase, to discharge the load to the second energy storage element until the voltage of the load reaches half of the second power supply voltage,
the fourth switch unit is configured to be switched on in the third phase, to discharge the load to ground until the voltage of the load reaches a ground voltage,
the third switch unit is further configured to be switched on in a third sub-phase of the fourth phase, so that the second energy storage element charges the load until the voltage of the load reaches half of the second power supply voltage, and
the second switch unit is further configured to be switched on in a fourth sub-phase of the fourth phase, so that the first energy storage element charges the load until the voltage of the load reaches the second power supply voltage.

18. The active pen according to claim 14, wherein
a switch unit connected between the first voltage generation circuit and the load in the switch circuit comprises a PMOS device,
a switch unit connected between each energy storage element and the load in the switch circuit comprises a first group of switches and a second group of switches in parallel, wherein the first group of switches comprise a PMOS device and a diode in series, the second group of switches comprise an NMOS device and a diode in series, and the diode in the first group of switches and the diode in the second group of switches have opposite conduction directions, and
a switch unit connected between the load and ground in the switch circuit comprises an NMOS device.

19. The active pen according to claim 18, wherein the first group of switches is configured to charge the load by the corresponding energy storage element, and the second group of switches is configured to discharge the load to the corresponding energy storage element.

20. A touch panel, comprising a drive circuit and a touch electrode connected to the drive circuit, wherein the drive circuit is configured to provide a drive voltage to the touch electrode, the drive circuit comprising:
a first voltage generation circuit, at least one energy storage element, and a switch circuit, wherein the first voltage generation circuit and the at least one energy storage element are connected to the load through the switch circuit, the first voltage generation circuit is configured to output a first power supply voltage, and
the switch circuit is configured to control the first voltage generation circuit to charge the load in a first phase until a voltage of the load reaches the first power supply voltage, control the load to discharge to the at least one energy storage element sequentially in a second phase, control the load to discharge to ground in a third phase, and control the at least one energy storage element to charge the load sequentially in a fourth phase, so that the voltage of the load rises and falls stepwise between different phases.
